(19) United States
(12) Patent Application Publication
(10) Pub. No.: US 2026/0341635 A1
(43) Pub. Date: Oct. 29, 2026

(54) High Intensity Field Ignitor Source for Semiconductor Chambers

(71) Applicant: Applied Materials, Inc., Santa Clara, CA (US)

(72) Inventors: Shreeram Jyoti DASH, Newark, CA (US); Kartik RAMASWAMY, San Jose, CA (US); Valentin N. TODOROW, Palo Alto, CA (US); Zhimin JIANG, Santa Clara, CA (US); Jonathan Howard WONG, Santa Clara, CA (US); Denis Martin KOOSAU, Pleasanton, CA (US); Daniel Sang BYUN, Campbell, CA (US)

(21) Appl. No.: 19/461,047

(22) Filed: Jan. 27, 2026

Related U.S. Application Data
(63) Continuation of application No. PCT/US2025/026200, filed on Apr. 24, 2025.

(51) Int. Cl. H01J 37/32; H10P 72/00

(52) U.S. Cl. CPC H01J 37/321; H01J 37/32146; H01J 37/32568; H01J 2237/0266; H10P 72/0421

(57) ABSTRACT

Apparatus for forming plasma in an inductively coupled plasma (ICP) chamber leverages electrodes that provide electric fields (E-fields) directly into the process volume. In some embodiments an apparatus for performing the methods may comprise a coil positioned above the process volume of the ICP chamber which generates inductively coupled plasma in the process volume from a first power source and at least one electrode positioned above the process volume with a first end and a second end where the second end is positioned at or below a lowermost surface of the coil. The first end is connected to a power source which can be the first power source or a particular point on the coil and radiates electric fields (E-fields) into the process volume.

### CROSS-REFERENCE TO RELATED APPLICATIONS

This application is a continuation of International Patent Application serial number PCT/US2025/026200, filed Apr. 24, 2025, which is herein incorporated by reference.

### FIELD

Embodiments of the present principles generally relate to semiconductor processing of semiconductor substrates.

### BACKGROUND

Semiconductor chambers may incorporate inductive coupling to generate plasma for processing substrates. An inductively coupled plasma (ICP) source may use one or more coils to generate the plasma in the process volume of the semiconductor chamber. Current flowing through the coils produces magnetic fields that inductively form plasma in the process volume. The inventors have observed, however, that sometimes an ICP chamber may have difficulty restriking or maintaining the plasma during some chamber operating conditions. As the complexity of semiconductor devices increases, so does the demand to expand chamber operating performance. The inability of a chamber to operate under all desired operating conditions is a serious challenge that must be overcome to enable the next generation of semiconductor devices.

Accordingly, the inventors have provided apparatus for increasing the useable operating conditions of ICP chambers.

### SUMMARY

Apparatus for increasing the operating window for ICP chambers using a high intensity field ignitor source are provided herein.

In some embodiments, an apparatus for forming plasma in an inductively coupled plasma (ICP) chamber may comprise at least one coil positioned above a process volume of the ICP chamber and configured to generate inductively coupled plasma in the process volume by generating magnetic fields (H-fields) that radiate into the process volume and where the at least one coil is connected to a first power source and at least one electrode positioned above the process volume of the ICP chamber with a first end and a second end, where the second end is positioned at or below a lowermost surface of the at least one coil, the first end is connected to a second power source independent of the first power source, and the second end is configured to radiate electric fields (E-fields) into the process volume.

In some embodiments, the apparatus may further include a second power source that is a variable power source, an E-field controller that is connected to and in communication with the second power source and is configured to adjust power to at least one of the at least one electrode, an E-field controller that adjusts power based on a process parameter of a process profile for the ICP chamber, a Faraday shield that is positioned between the at least one coil and the process volume and where no Faraday shield is positioned between the second end of the at least one electrode and the process volume, a second end of the at least one electrode that has a second end surface area, a second end surface area that is smaller than a cross section of the at least one electrode, greater than a cross section of the at least one electrode, or equal to a cross section of the at least one electrode, a second end of the at least one electrode that is adjustably connected to a pad and where a distance between the process volume and the pad of the second end of the at least one electrode can be altered, and/or at least one electrode that is a plurality of electrodes and wherein the second end of at least two of the plurality of electrodes are connected to one pad.

In some embodiments, an apparatus for forming plasma in an inductively coupled plasma (ICP) chamber may comprise at least one coil positioned above a process volume of the ICP chamber and configured to generate inductively coupled plasma in the process volume by generating magnetic fields (H-fields) that radiate into the process volume and where the at least one coil is connected to a first power source and at least one electrode positioned above the process volume of the ICP chamber with a first end and a second end, where the second end is positioned at or below a lowermost surface of the at least one coil, the first end is connected to a second power source independent of the first power source, the second end is configured to radiate electric fields (E-fields) into the process volume, a floating Faraday shield is positioned between the at least one coil and the process volume, at least one electrode is a plurality of electrodes, and the at least one coil includes an inner coil and an outer coil.

In some embodiments, the apparatus may further include a second end of the at least one electrode that has a second end surface area, a second end surface area that is smaller than a cross section of the at least one electrode, greater than a cross section of the at least one electrode, or equal to a cross section of the at least one electrode, a second end of the at least one electrode that is adjustably connected to a pad and where a distance between the process volume and the pad of the second end of the at least one electrode can be altered, and/or at least one electrode that is a plurality of electrodes and where the second end of at least two of the plurality of electrodes are connected to one pad.

In some embodiments, an apparatus for forming plasma in an inductively coupled plasma (ICP) chamber may comprise a first RF power source electrically connected to at least one coil of the ICP chamber where the at least one coil is configured to inductively couple with plasma formed in a process volume of the ICP chamber and a second RF power source electrically connected to at least one electrode with an unterminated end of the at least one electrode positioned radially outward of the at least one coil and configured to capacitively couple with plasma formed in the process volume of the ICP chamber, the first RF power source is configured to generate a synchronization signal which is sent to the second RF power source when power from the first RF power source is turned ON and the second RF power source is configured to pulse power when the synchronization signal is received from the first RF power source.

In some embodiments, the apparatus may further include a second RF power source that is configured to pulse power with a pulse having a pulse width of 1 μs to 10,000 ms, an optical sensor that is positioned in the ICP chamber to monitor states of plasma and a second RF power source that is configured to alter a pulse width based on feedback from the optical sensor, a distance from the unterminated end of the at least one electrode to the process volume that is adjustable, a distance that is automatically adjustable, and/or at least one electrode and power feed structure are configured to operate in a resonant state.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of an inductively coupled plasma (ICP) process chamber in accordance with some embodiments of the present principles.

FIG. 2 depicts cross-sectional views of ICP sources and an isometric view of a coil assembly in accordance with some embodiments of the present principles.

FIG. 3 depicts isometric views of lid heaters for an ICP process chamber in accordance with some embodiments of the present principles.

FIG. 4 depicts isometric views of electrode assemblies in accordance with some embodiments of the present principles.

FIG. 5 depicts an isometric view of an electrode assembly attached to a coil assembly in accordance with some embodiments of the present principles.

FIG. 6 depicts isometric views of electrode pads in accordance with some embodiments of the present principles.

FIG. 7 depicts an isometric view of an electrode pad in accordance with some embodiments of the present principles.

FIG. 8 depicts an isometric view of a pair of electrode pads in accordance with some embodiments of the present principles.

FIG. 9 depicts an isometric view of electrodes and electrode pads on a lid of a process chamber in accordance with some embodiments of the present principles.

FIG. 10 depicts an isometric view of a CCP RF power source, electrodes, and electrode pads on a lid of a process chamber in accordance with some embodiments of the present principles.

FIG. 11 depicts isometric views of a U-shaped electrode housing for a CCP RF power feed in accordance with some embodiments of the present principles.

FIG. 12 is a graph depicting synchronized ICP power signals and CCP power signals in accordance with some embodiments of the present principles.

FIG. 13 depicts an equivalent schematic of the inductances and capacitances of a CCP RF power feed system from the CCP RF generator to the electrode pads to process chamber ground in accordance with some embodiments of the present principles.

FIG. 14 is a method of projecting electric fields into a process volume of an ICP process chamber in accordance with some embodiments of the present principles.

FIG. 15 depicts a top-down view of electric fields in a process volume of a process chamber in accordance with some embodiments of the present principles.

FIG. 16 depicts a top-down view of electric fields in a process volume of a process chamber with a floating heater in accordance with some embodiments of the present principles.

FIG. 17 is another method of projecting electric fields into a process volume of an ICP process chamber in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The apparatus herein provides an inductively coupled plasma (ICP) source that includes a high intensity field ignitor assembly that enables the operating window of an ICP process chamber to be increased. The high intensity field ignitor assembly advantageously permits maintaining plasma at lower pressures and permits easier plasma ignition and restriking which enables longer off times during plasma source pulsing (increases the process restriking/ignition window). The ICP source of the present principles reduces the exposure of the electric fields (E-fields) produced by the coils of the ICP source to the process volume of the ICP process chamber while selectively controlling E-fields required for plasma ignition/restriking using the high intensity field ignitor assembly. The selective E-field control permits high quality plasma formation in the process volume (H-field exposure from the coils) while enabling increased restriking performance “on demand” (controlled E-field exposure from high intensity field ignitor assembly), essentially enabling the E-fields and H-fields to be tuned independently. The present techniques also beneficially enable an ICP chamber to operate with a floating Faraday shield without adding auxiliary sources or a retractable shield to enhance restriking performance.

When electrical current is flowed through the coils of an ICP source, the electrical current causes both magnetic fields and electrical fields to radiate from the coils. In general, E-fields in the process volume are undesirable due to detrimental effects that can occur in the process volume such as, but not limited to, oscillating plasma potential, lid sputtering, and E-to-H field transition instabilities, and the like. Conventional ICP process chambers often use grounded Faraday shields to block the E-fields generated by the coils from entering into the process volume. However, to strike the plasma, the conventional ICP chambers must retract the Faraday shield to expose the coils to ignite the plasma or have an auxiliary plasma striking source (separate plasma source connected to the process chamber) to generate E-fields to ignite the plasma.

The inventors have observed that low power plasma ignition and complicated pulsed plasma schemes are a trend for advanced logic plasma etching processes as well as other processes. However, the advanced pulsing schemes introduce plasma stability issues which prevents utilizing complicated pulsing in the process chambers. One considered approach is to increase the striking/re-ignition capability of an ICP source, but inductively coupled plasma is H coupled plasma and has limited ability to strike/re-ignite plasma. In addition, current tools using ICP systems have hardware limitations that prevent achieving low power plasma in conjunction with complicated pulsing schemes, such as, for example, a pulse duty cycle with an OFF time of greater than 10 ms. An ICP pulse has power ON and power OFF stages in a given duty cycle. The inventors have observed that if the OFF stage is longer than 5 ms, re-ignition for the next power ON stage will be problematic. The plasma ignition and re-ignition requires CCP coupling to generate seed electrons for plasma generation and to transition from CCP coupling (low plasma density) to ICP coupling (high plasma density). Thus, the inventors have found that increased CCP coupling is key to obtaining an ICP system that can achieve low power plasma ignition and complicated pulsing schemes. The inventors have discovered an ICP and CCP combined system that leverages the advantages of both ICP and CCP to achieve complicated plasma processing via low power plasma ignition and complicated pulsing schemes such as, but not limited to, long OFF times and the like.

In some embodiments of the present techniques, one or more E-field exposure zones in an ICP source are formed and leveraged in conjunction with unterminated electrodes (high E-field ignitors) to bring the E-field discharge closer to the lid of the chamber. The configuration maximizes E-field penetration (capacitive coupling) into the process volume while retaining an H-field only operation using the coils of the ICP source. In some embodiments, the E-field exposure zones are absent any Faraday shielding while areas outside of the E-field exposure zones may incorporate Faraday shielding to block any E-fields emanating directly from the coils. The E-field exposure zones allow unencumbered E-fields to radiate through the lid and into the process volume. Electrodes with unterminated ends are positioned in the E-field exposure zones to provide E-field exposure directly into the process volume to enhance restriking performance. The current or voltage applied to the electrodes can be varied in, for example but not limited to, current level, voltage level, frequency, duration, and/or pulse timing, and the like. In some embodiments, the unterminated ends of the electrodes may have a given surface area or “pad” that allows for control of the E-field size, and subsequently E-field density projected into the process volume. The distance between the pad and the lid may also be varied to further tune the E-field projection into the process volume. In some embodiments, the distance from the pad to the lid may be fixed and/or tunable by moving the pad to increase or decrease the distance between the pad and the lid. The number and/or spacing of electrodes may also be varied to further tune the E-fields projected into the process chamber.

In some embodiments, the RF power source for the electrodes originates from the ICP coils (e.g., inner coils or outer coils, etc.). In some embodiments, the RF power source for the electrodes originates from a separate RF power source or generator than the RF power sources used for powering the ICP coils. Surfaces of the unterminated electrodes closest to the process volume of the process chamber may be zero to approximately 1 inch away from the uppermost surface of the lid. The electrodes can be positioned radially at any location above or on the lid and with the unterminated ends at or below a lowermost surface of the ICP coils.

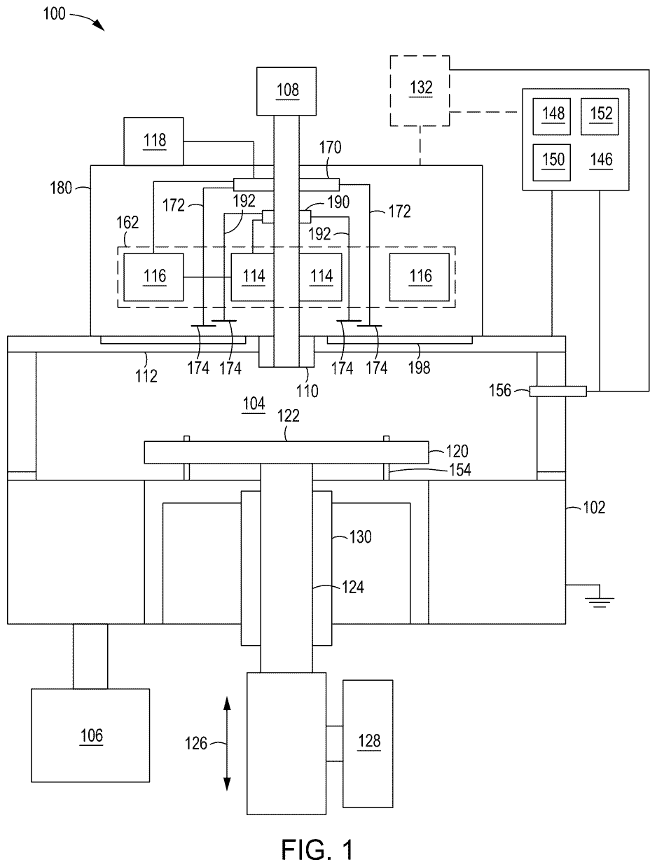

FIG. 1 depicts a cross-sectional view of an example of an ICP chamber 100 in which the present techniques are applicable but is not meant to be limiting. The ICP chamber 100 has a lid 112 that may be formed from an aluminum nitride or aluminum oxide-based material and the like. A lid heater 198 may be positioned at or on the upper surface of the lid 112. The ICP chamber 100 includes an ICP source assembly 180 which includes a coil assembly 162 and one or more RF plasma sources 118. In some embodiments, the ICP source assembly 180 may be removable from the lid 112. In some embodiments, a hinge or pivot point (not shown) allows the ICP source assembly 180 to tilt up and back to expose the coil assembly 162. The ICP chamber 100 includes chamber walls 102 that enclose a process volume 104 where substrate processing occurs. The ICP chamber 100 also includes a pumping system 106 to control the pressure within the ICP chamber 100 and to expel unwanted gases before, during, or after a substrate has been processed. The pumping system 106 may also include a throttling gate valve to assist in maintaining the pressure within the ICP chamber 100. In some instances, the pumping system 106 may also include a roughing pump for fast pump down and a turbomolecular pump for higher vacuum pressures.

A gas delivery system 108 provides process gases into the process volume 104 through a nozzle 110. The gas delivery system 108 may include showerheads, gas rings, and/or nozzles and the like. In some embodiments, plasma is inductively coupled in the process volume 104 using a coil assembly 162 with dual coil antennas that include one or more inner coils 114 and one or more outer coils 116. In some embodiments, the coil assembly 162 may have inner coils, middle coils (not shown), and outer coils. Plasma coupling power is provided by one or more RF plasma sources 118 with one or more frequencies, waveforms, and/or power levels, etc. If more than one frequency is used, the power may be generated by a single multi-channel RF generator or two separate RF generators that are synchronized. In some embodiments, the one or more RF plasma sources 118 may provide frequencies of approximately 100 kHz to approximately 250 MHz. The supplied RF power may be continuous and/or pulsed. The one or more RF plasma sources 118 may also include one or more RF match networks (not shown) positioned between the one or more RF plasma sources 118 and the coil assembly 162 for adjusting impedances of the power sources to match the load impedance of the ICP chamber 100 for optimal power transfer. In some embodiments, more than two RF sources may be used.

In some embodiments, a first power delivery adapter 170 may be connected to the one or more RF plasma sources 118 to distribute power to one or more outer coils 116 and to a first set of electrodes 172. The first set of electrodes 172 may include one or more electrodes with each electrode having an electric field discharge surface or pad 174. The one or more outer coils 116 are electrically connected to the one or more inner coils 114. In the example, which is not meant to be limiting, RF current flows from the one or more RF plasma sources 118 through the one or more outer coils 116 and then into the one or more inner coils 114 and then to the RF ground return. In some embodiments, the one or more RF plasma sources 118 may be first connected to the one or more inner coils 114 and RF current may flow first into the one or more inner coils 114 and then into the one or more outer coils 116 and then to the RF ground return. In the example, a second power delivery adapter 190 may be connected to the one or more inner coils 114 to distribute power to a second set of electrodes 192. The second set of electrodes 192 may include one or more electrodes with each electrode having an electric field discharge surface or pad 174. In the example of FIG. 1, the second set of electrodes 192 are electrically connected to the one or more inner coils 114 which, in the example, have a lower RF voltage level compared to the first set of electrodes 172 that are connected to the one or more outer coils 116. The lower voltage level at the one or more inner coils 114 is due to the voltage drop over the one or more outer coils 116.

The voltage levels on the first set of electrodes 172 and the second set of electrodes 192 can be varied by adjusting the electrical connection point on the respective coils (or by connecting to the first power delivery adapter 170 or the second power delivery adapter 190). The first power delivery adapter 170 and the second power delivery adapter 190 are optional as the first set of electrodes 172 and/or the second set of electrodes 192 may be connected directly to the coils rather than to a power delivery adapter. In some embodiments, the first set of electrodes 172 and the second set of electrodes 192 may be connected to the same electrical connection point. In some embodiments, the first set of electrodes 172 and the second set of electrodes 192 may be connected the same or to different power sources other than the one or more RF plasma sources 118. The different power sources may also be controlled by an optional electrical field controller 132. The power source flexibility allows for different sets of electrodes to have different E-field voltages and/or durations. In some embodiments, each individual electrode may be controlled to permit different E-fields for each individual electrode. The pad 174 may also have different surface areas for each individual electrode and/or for each set of electrodes and the like.

A pedestal 120 includes an upper portion 122 with lift pins 154 and a lower portion 124. The pedestal 120 may have vertical motion 126 provided by a lifting assembly 128. A bellows 130 allows the vertical motion 126 to occur without breaking the seal of the process volume 104. The ICP chamber 100 may also include a controller 146. The controller 146 controls the operation of the ICP chamber 100 using a direct control or alternatively, by controlling the computers (or controllers) associated with the ICP chamber 100. In operation, the controller 146 enables data collection and feedback to optimize performance of the ICP chamber 100. In some embodiments, the controller 146 may interact with the optional electric field controller 132 that controls the power to the electrodes. The controller 146 generally includes a Central Processing Unit (CPU) 148, a memory 150, and a support circuit 152. The CPU 148 may be any form of a general-purpose computer processor that can be used in an industrial setting. The support circuit 152 is conventionally coupled to the CPU 148 and may comprise a cache, clock circuits, input/output subsystems, power supplies, and the like. Software routines, such as used in the methods and/or apparatus as described herein may be stored in the memory 150 and, when executed by the CPU 148, transform the CPU 148 into a specific purpose computer (controller 146). The software routines may also be stored and/or executed by a second controller (not shown) that is located remotely from the ICP chamber 100.

The memory 150 is in the form of computer-readable storage media that contains instructions, when executed by the CPU 148, to facilitate the operation of the semiconductor processes and equipment. The instructions in the memory 150 are in the form of a program product such as a program that implements the apparatus of the present principles. The program code may conform to any one of a number of different programming languages. In one example, the disclosure may be implemented as a program product stored on a computer-readable storage media for use with a computer system. The program(s) of the program product define functions of the aspects. Illustrative computer-readable storage media include, but are not limited to: non-writable storage media (e.g., read-only memory devices within a computer such as CD-ROM disks readable by a CD-ROM drive, flash memory, ROM chips, or any type of solid-state non-volatile semiconductor memory) on which information is permanently stored; and writable storage media (e.g., floppy disks within a diskette drive or hard-disk drive or any type of solid-state random access semiconductor memory) on which alterable information is stored. Such computer-readable storage media, when carrying computer-readable instructions that direct the functions of ICP chamber 100 and/or the electrical field controller as described herein, are aspects of the present principles.

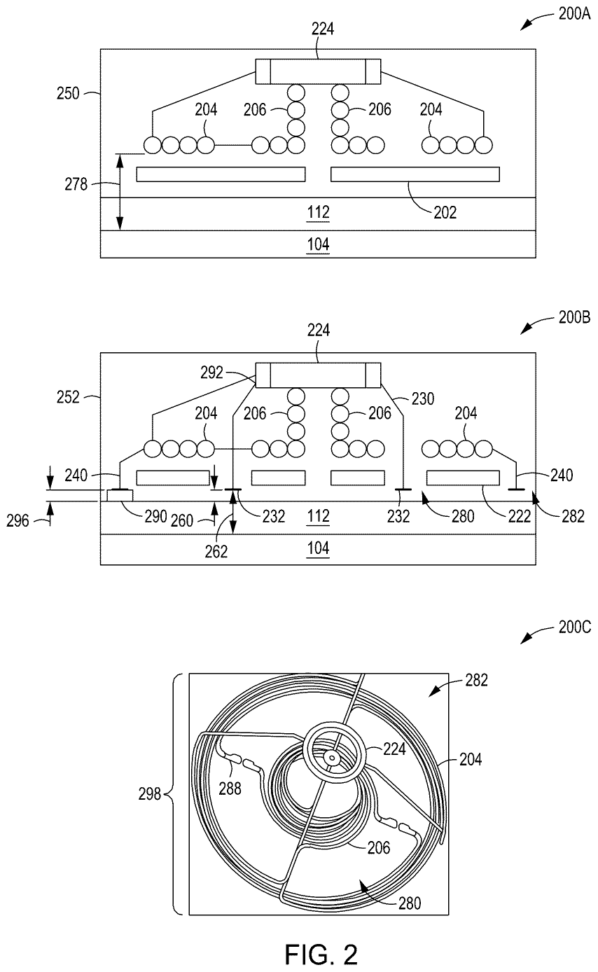

In a cross-sectional view 200A of FIG. 2, an ICP source 250 positioned above the lid 112 has outer coils 204 and inner coils 206 that are separated from the lid 112 by a Faraday shield 202 and connected to a power source (not shown) via adapter 224. In some embodiments, the Faraday shield 202 may be a floating Faraday shield that is not grounded to the chamber ground. The Faraday shield 202 is used to block E-fields generated by RF current flowing through the outer coils 204 and the inner coils 206 from reaching the process volume 104 below the lid 112 (see, e.g., FIG. 1). The magnetic or H-fields generated by the outer coils 204 and the inner coils 206 pass through the Faraday shield 202 and generate inductively coupled plasma within the process volume 104. Because little of the E-fields penetrate into the process volume 104, igniting or restriking the plasma is difficult. In some cases, the Faraday shield 202, in whole or in part, is retracted to expose at least a portion of the coils to allow for easier plasma ignition. Even with the retraction of all or a part of the Faraday shield 202, the distance 278 between the inner coil 206 and the outer coil 204 and the process volume 104 makes quick restriking of the plasma difficult when using pulsed plasma power and the like. The longer distance from the E-field source (inner and outer coils) to the process volume 104 requires longer restrike durations, eliminating some pulsing waveforms with short on-times and long off-times. The longer distance from the E-field source (inner and outer coils) also reduces the transmitted E-field strength in the process volume which makes low pressure restriking in the process volume 104 more difficult.

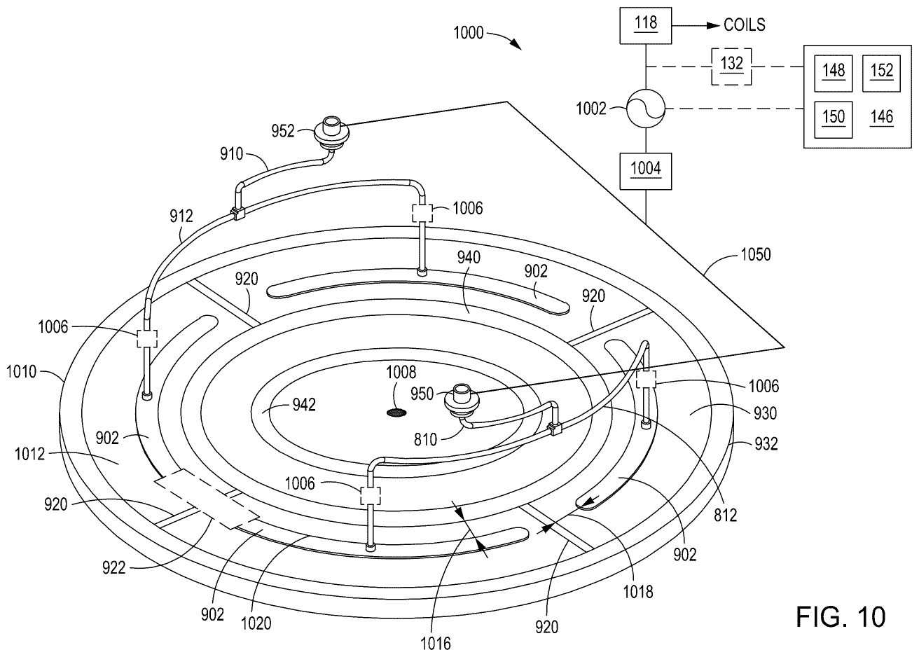

The inventors have discovered that by creating E-field exposure zones between the coils (the inner zone 280) and/or outside of the outer coil 204 (outer zone 282), unterminated electrodes (e.g., inner electrodes 230 and/or outer electrodes 240) may be used in the zones to provide controllable E-fields in the process volume 104 to enhance plasma ignition, maintenance, and restriking performance and the like as depicted in a cross-sectional view 200B of FIG. 2. In some embodiments, a segmented Faraday shield 222 may be used to provide open space (E-field exposure zones) for placement of the unterminated electrodes. In some embodiments, the electrodes may have a first end 292 connected to a power source such as, but not limited to, an inner coil, an outer coil, a standalone electric field power source (e.g., RF generator 1002 of FIG. 10, etc.), and/or an RF plasma power source (e.g., RF plasma source 118 of FIG. 1), and the like. The electrodes have a second end 294 (unterminated electrode end) which may have a pad 232 with a given surface area that allows for additional tuning of the E-field size and subsequently the E-field density projected into the process volume 104. In some embodiments, the pad 232 may be adjustably connected to the electrode, for example but not limited to, threads or a sliding rod with a set screw and the like that allow the pad to extend or shorten the electrode length, decreasing or increasing the distance 262 between the second end 294 and the process volume 104. The distance 260 above the lid 112 can also be set using an insulator or spacer 290 and varying the thickness 296 of the spacer 290. In some embodiments, the spacer 290 may be formed of a high temperature resistant dielectric material such as, but not limited to, polytetrafluoroethylene (PTFE) and/or polyether-ether-ketone (PEEK), and the like. In some embodiments, the spacer 290 may be formed of ceramic materials and may rest on and cover a substantial portion or a small portion of the lid 112. In some embodiments, the pad 232 may not be supported by a surface of the lid 112 or a spacer 290 and may be suspended in space within the ICP source assembly 252.

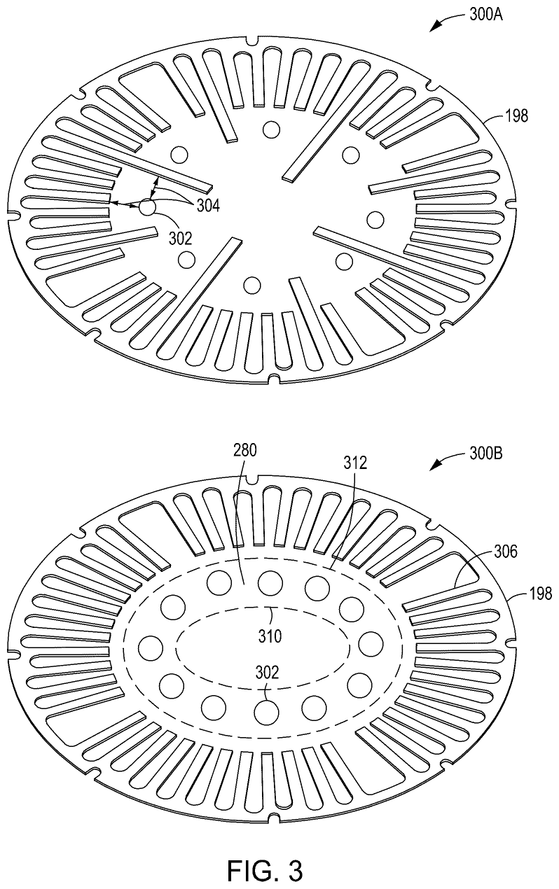

A coil assembly 298 with inner coil 206 and outer coil 204 is depicted in an isometric view 200C of FIG. 2. The inner zone 280 and/or the outer zone 282 is made available for positioning electrodes. Care is taken to ensure that electrodes are not spaced closely to existing coil connections 288 and/or other conductive components besides the coils of an ICP source to avoid arcing or other negative impacts when the electrodes are energized. For example, the lid heater 198 of FIG. 1 may affect the placement of the electrodes 302 as depicted in an isometric view 300A of FIG. 3. The electrodes 302 are positioned such that the distances 304 between the electrode 302 and the lid heater 198 are maintained to ensure that no arcing or other issues (e.g., heater element shorting, etc.) result from the electrode placement. In some embodiments, modifications may be made to existing structure within the ICP chamber, for example but not limited to, shortening of some fingers 306 of the lid heater 198 to allow for more optimal placement of the electrode 302 and/or to allow for a greater number of electrodes, etc. as depicted in an isometric view 300B of FIG. 3. Dashed line 312 indicates the approximate position of the outer coils and dashed line 310 indicates the approximate position of the inner coils. In the nonlimiting example, the electrodes 302 are positioned within the inner zone 280 but may also be positioned in the outer zone 282.

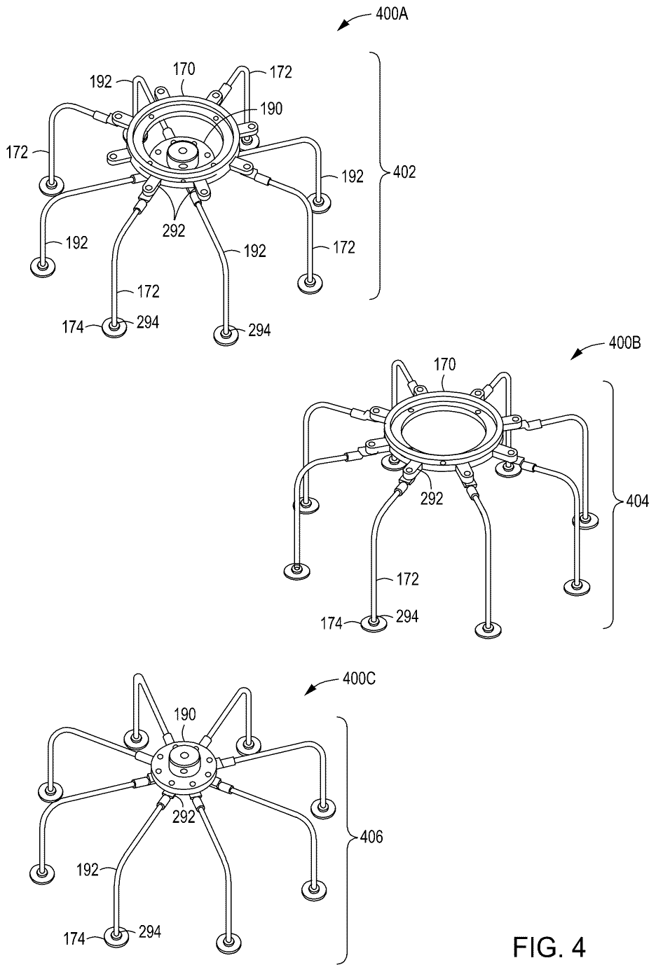

An isometric view 400A of FIG. 4 depicts a first electrode assembly 402 with a first set of electrodes 172 and a second set of electrodes 192 (a variant of a combination of the second electrode assembly 404 and the third electrode assembly 406 described below). The first set of electrodes 172 are attached to a first power delivery adapter 170 at a first end 292 of each electrode and attached to a pad 174 at a second end 294 of each electrode. The second set of electrodes 192 are attached to a second power delivery adapter 190 at a first end 292 of each electrode and attached to a pad 174 at a second end 294 of each electrode. In some embodiments, the pad 174 may be circular, rectangular, triangular, kidney shaped, and/or any other shape and is not limited to what is depicted in FIG. 4. The first power delivery adapter 170 and the second power delivery adapter 190 may be connected to a single power source or connected to different power sources with the same or different voltage and/or current levels. In some embodiments, the different power sources may be pulsed in synch or asynchronously. The number of electrodes in each set of electrodes may also be any number of electrodes. An isometric view 400B of FIG. 4 depicts a second electrode assembly 404 with a first set of electrodes 172 that are attached to a first power delivery adapter 170 at a first end 292 of each electrode and attached to a pad 174 at a second end 294 of each electrode. In some embodiments, the second electrode assembly 404 is only connected to an outer coil and/or an outer coil power source and the like. An isometric view 400C of FIG. 4 depicts a third electrode assembly 406 with a second set of electrodes 192 that are attached to a second power delivery adapter 190 at a first end 292 of each electrode and attached to a pad 174 at a second end 294 of each electrode. In some embodiments, the third electrode assembly 406 is only connected to an inner coil and/or an inner coil power source and the like.

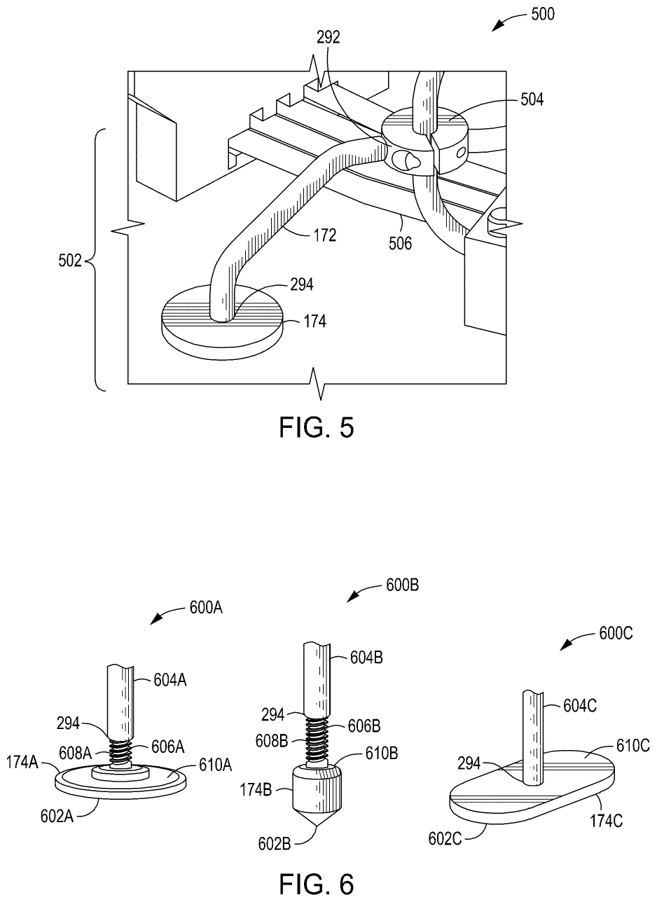

In some embodiments, an electrode assembly 502 may comprise an electrode 172 with a first end 292 connected directly to a coil 506 and a second end 294 connected to a pad 174 as depicted in an isometric view 500 of FIG. 5. The coil 506 may be any coil such as an inner coil, a middle coil, and/or an outer coil. In other words, the electrode assembly 502 may include one or multiple electrode assemblies positioned on only a single coil or on multiple coils. The voltages of the electrode assembly 502 will be approximately the voltage at the attachment location of the electrode assembly 502 to the coil 506. By altering the attachment position, the E-field projected into the process volume by the electrode assembly 502 can be tuned. In some embodiments, a collar 504 may be used to attach the first end 292 of the electrode 172 to the coil 506.

In some embodiments, the pad 174 of the electrodes may be altered to also provide a tuning capability for the E-field projected into the process volume as depicted in FIG. 6. In some embodiments, the second end surface area or pad may be smaller than a cross section of the electrode, greater than a cross section of the electrode, or equal to a cross section of the electrode. In a view 600A of FIG. 6, the pad 174A has a bottom surface 602A with a circular area from which the E-field is projected into the process volume 104 (see, e.g., FIG. 1). The circular area can be altered to adjust the E-field density (larger is lower density but covers more area in the process volume, smaller is higher density but covers less area in the process volume, etc.). The second end 294A of the electrode 604A accepts a threaded portion 606A of an extension 608A that extends upward from a top surface 610A of the pad 174A. The threaded portion 606A allows the pad 174A to be adjusted closer to the process volume 104 or further away from the process volume 104 which subsequently adjusts the E-field intensity and projection into the process volume 104.

In a view 600B of FIG. 6, the pad 174B has a bottom surface 602B that comes to a point with minimal surface area from which the E-field is projected into the process volume 104 (see, e.g., FIG. 1). The point of the bottom surface 602B concentrates the E-field projected into the process volume 104 to increase the density of the E-field and maximize penetration at a single point into the process volume 104. The second end 194 of the electrode 604B accepts a threaded portion 606B of an extension 608B that extends upward from a top surface 610B of the pad 174B. The threaded portion 606B allows the pad 174B to be adjusted closer to the process volume 104 or further away from the process volume 104 which subsequently adjusts the E-field intensity and projection into the process volume 104. In a view 600C of FIG. 6, the pad 174C has a bottom surface 602A with an oval area from which the E-field is projected into the process volume 104 (see, e.g., FIG. 1). The oval area size can be altered to adjust the E-field density (larger is less density but covers more area in the process volume, smaller is higher density but covers less area in the process volume, etc.). The second end 294 of the electrode 604C is affixed to a top surface 610C of the pad 174C. In some embodiments, a PEEK screw, for example but not limited to, may be inserted through the bottom surface 602C of the pad 174C and into the second end 294 of the electrode 604C via a hole through the pad 174C.

FIG. 6 depicts example pads and is not meant to be limiting. The pads may be any shape, and the shape can be adjusted based on particular desired voltage levels, intensity levels, and the like for a given process being performed in the process volume 104. The pads may also be attached to the electrodes in a manner that allows for extension/retraction to adjust the distance between a bottom surface of the pad and the process volume 104. Examples of extension/retraction apparatus may include the threading depicted in views 600A and 600B along with other apparatus such as, but not limited to, a shaft extension from an upper surface of the pad that engages with a hole in the second end of the electrode where the shaft length is set by a set screw in the second end of the electrode and the like.

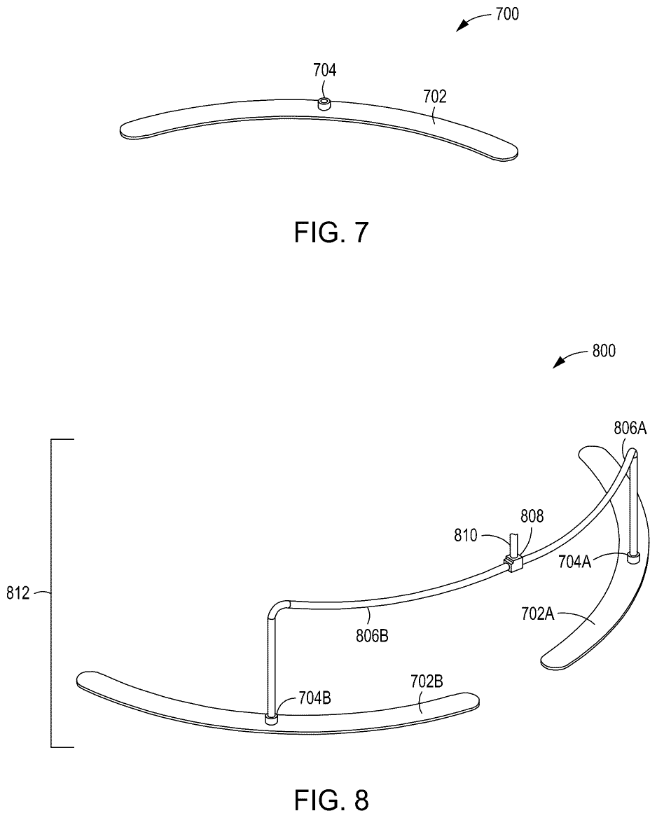

In a view 700 of FIG. 7, a further example of a pad 702 for an electrode is depicted. The pad 702 may include a connection 704 for the electrode (not shown). In a view 800 of FIG. 8, a first half 812 of an electrode assembly is depicted. The first half 812 of an electrode assembly includes a first pad 702A with a first connection 704A that joins a first section 806A of the electrode and a second pad 702B with a second connection 704B that joins a second section 806B of the electrode. The first section 806A of the electrode and the second section 806B of the electrode are connected via a third connection 808 to a first power feed section 810 of the electrode. In a view 900, the first half 812 of the electrode is positioned on or above a dielectric window 930 of a lid 932 and a second half 912 of the electrode is positioned on or above the dielectric window 930 of the lid 932 of the process chamber. The pads 902 are positioned to cover the four quadrants of the process chamber while avoiding contact with gas line 920. An optional bridge 922 may connect each of the pads 902 to an adjacent pad to provide stability of the pads 902 while allowing the gas line 920 to pass underneath. The optional bridge 922 may be made of a non-conductive material and/or a conductive material which may electrically join two or more quadrants together as one pad. The pads 902 are positioned radially outward of the outer coils 940. The outer coils 940 are positioned radially outward of the inner coils 942. The first power feed section 810 is electrically connected to a first power feed point 950 and the second power feed section 910 is electrically connected to a second power feed point 952. In some embodiments, each of the pads 902 may be connected to different individual power sources that operate independently or a single power source.

In a view 1000 of FIG. 10, the first power feed point 950 and the second power feed point 952 are electrically connected via an electrode power feed 1050 to an RF generator 1002 via a match network 1004 for supplying CCP power to the pads 902. In some embodiments, more than one RF generator may be used to supply power to each half of the electrode assembly or to supply power to each individual pad of the electrode assembly. In some embodiments, the one or more RF generators may also be connected to the controller 146 of the process chamber and/or to the optional electrical field controller 132. The optional electrical field controller 132 may also reside within the controller 146 in some embodiments. By implementing a dual feed to each pair of pads 902, a more uniform power is applied to the pads 902 which in turn produces a more uniform electrical field within the process volume of the process chamber. The number of pads 902 and/or the number of power feed points to the pads 902 may selected on a cost-benefit analysis, as increasing the complexity gives greater uniformity control but increases the cost of the system both in hardware but also in maintenance costs.

In some embodiments, one or more optional step motors 1006 may be used to raise and lower the pads 902 to vary the distance between the lowermost pad surface and the uppermost surface of the dielectric window 930. The optional step motors 1006 may be positioned to raise and lower each pad individually or positioned to raise and lower multiple pads at the same time. The raising and lowering of the pads 902 directly affects the capacitance of the pads 902 to the chamber ground. The number of electrodes may be from a single electrode up to 20 electrodes to form a uniform electrical field in the process volume of the process chamber. The radial location of the electrodes from the center 1008 of the lid 932 to the edge 1010 of the lid 932 directly impacts the plasma uniformity in the process volume. The distance from the uppermost surface 1012 of the dielectric window 930 to the lowermost surface of the electrode (e.g., lowermost surface of pad or lowermost point of electrode) may be from zero (in contact) to approximately 1 inch above the uppermost surface 1012 of the dielectric window 930 (see, e.g., distance 260 of FIG. 2). With optional step motors 1006, the height of the CCP electrode can be modulated by the optional step motors to control CCP coupling strength between the electrode and the plasma in the process volume of the process chamber. The distance 1016 between an innermost edge 1020 of a pad 902 and a coil set such as the outer coils 940 may be from approximately 0.25 inches to approximately 1 inch. The greater the distance, the higher the breakdown voltage between the pad 902 and the outer coils 940. In some embodiments, the gas lines 920 may also be conductive. In such cases, the distance 1018 between the pad 902 and the gas line 920 may be approximately 0.5 inches to approximately 1.5 inches. The greater the distance, the higher the breakdown voltage between the pad 902 and the gas line 920.

In some embodiments, a power feed structure 1102 is mounted on a plate 1104 and positioned above the coils and pads as depicted in a view 1100 of FIG. 11. Power from an RF generator is connected to a main feed point 1106 which is connected to a conductor 1110 (e.g., electrode power feed 1050 of FIG. 10, etc.) that is positioned within the power feed structure 1102. For example, the main feed point 1106 may be connected to the RF generator 1002 via the match network 1004 of FIG. 10. The conductor 1110 is then electrically connected, for example, to the first power feed point 950 and the second power feed point 952 at end locations 1108. In some embodiments, the power feed structure 1102 has a U-shaped conductor to account for the match network of the RF generator (e.g., RF generator 1002, match network 1004 of FIG. 10, etc.).

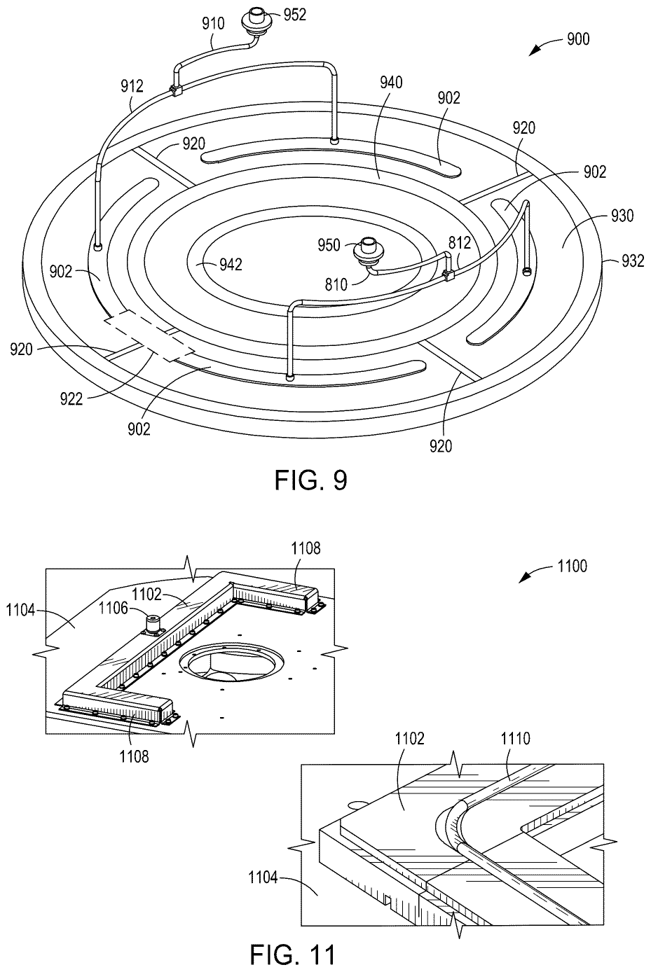

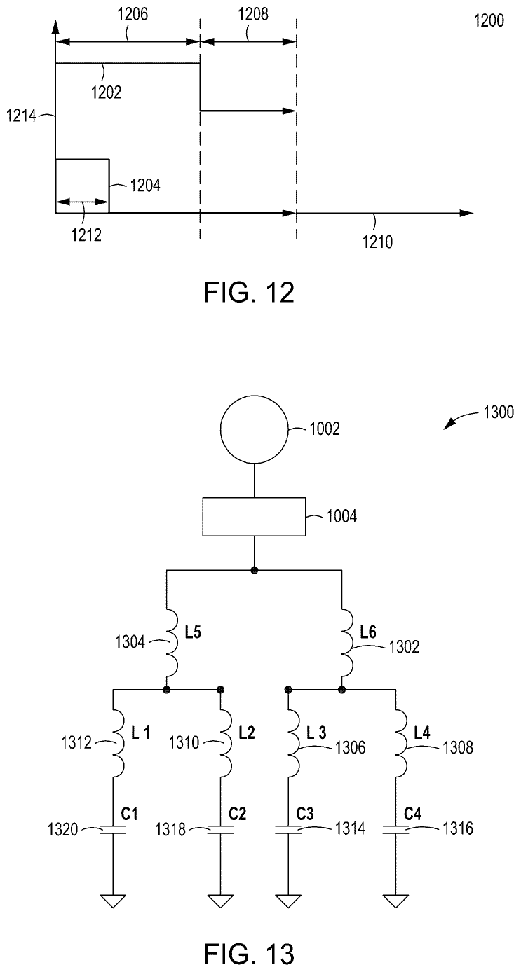

In some embodiments, a lid heater may be used as a floating Faraday shield (e.g., such as Faraday shield 202 of FIG. 2, etc.) to enhance the electrical field uniformity. The electrodes may also be positioned outside of the outer coils in the outer zone as depicted in FIGS. 9 and 10. The electrodes can then be electrically connected to an independent RF generator (such as RF generator 1002 of FIG. 10) via a match network (e.g., match network 1004 of FIG. 10). By utilizing a separate RF generator independent of the RF generators for powering the coils, greater tunability and control precision over the electrical fields in the process volume can be achieved. In a graph 1200 of FIG. 12, an example of pulse timing between the independent CCP RF generator for the electrodes and the ICP RF generator for the coils of an ICP process chamber is depicted. The X-axis 1210 represents time while the Y-axis 1214 represents the magnitude of the pulses. In some embodiments, the timing of the pulses of the CCP RF generator and the ICP RF generator can be accomplished manually in a predetermined fashion such as that depicted by the graph 1200. A Transistor-Transistor Logic (TTL) synchronization signal can be sent by the ICP RF generator or by another controller to the CCP RF generator to synchronize the timing between the generators. The CCP RF generator signal 1204 is pulsed at the same time that the ICP RF generator signal 1202 starts an ON state 1206 (which ends at an OFF state 1208). The pulse width 1212 of the CCP RF generator may be from approximately 1 μs to approximately 10,000 ms.

In some embodiments, an optical sensor (see, e.g., optical sensor 156 of FIG. 1) may be used to detect the plasma state in the process volume 104 and provide feedback, for example, to the controller 146 and/or the optional electrical field controller 132 (see FIG. 1). The feedback of the plasma state can be used to automatically control the timing and/or pulse width of the CCP RF generator. For example, when the CCP RF generator supplies power to the electrodes (ON state), plasma is ignited in the process volume of the process chamber which causes an increase in optical intensity. The optical sensor 156 detects the increased optical intensity and sends the feedback to the controller 146 which then sends a signal to the CCP RF generator to change to an OFF state. The feedback allows the pulse width to be automatically adjusted to minimize the ON state of the CCP RF generator to avoid detrimental side effects. For example, long ON states of the CCP RF generator may lead to unwanted sputtering from the lid and/or substrate cross uniformity issues.

In a view 1300 of FIG. 13, an electrical schematic of an example resonating circuit that can be produced from the electrode assembly and independent power source of FIG. 10 is depicted. The methods and apparatus of the present techniques can be used to design the system as a resonator for a given input RF frequency (CCP RF generator), where the total impedance is zero. The methods and apparatus can also be used to produce a non-resonating circuit. Equivalent inductances L5 and L6 1302, 1304 represent the electrode portions that feed CCP power from the RF generator 1002 down to the first branch point of each half of the electrodes. Equivalent inductances L1-L4 1306-1312 represent the electrode portions from the first power feed point 950 and the second power feed point 952 to the four pads 902, respectively. Equivalent capacitances C1-C4 1314 to 1318 represent the capacitance between the four pads 902 and the surrounding process chamber grounds, respectively. In some instances, the closest process chamber ground may be the top edge of the chamber walls. The LC network can be tuned by adjusting the one or more lengths of each of the sections of the electrodes along with the distances between the pads of the electrodes and surrounding chamber grounds. In some embodiments, the resonant frequency may be predetermined based on the adjustments made to the lengths of the electrode sections and the placement (distance) of the electrode pads. In some embodiments, the distances of the pads to chamber ground may be adjusted manually or automatically by, for example, controlling step motors that adjusts the lowermost surfaces of the pads above the uppermost surface of the dielectric window of the lid. Adjustments of the distance may also be made manually, for example, by screwing and unscrewing the pads on the electrodes or lengthening or shortening the electrodes connected to the pads. The distance is altered for uniformity control of the electric fields within the process volume and to reduce lid sputtering risks.

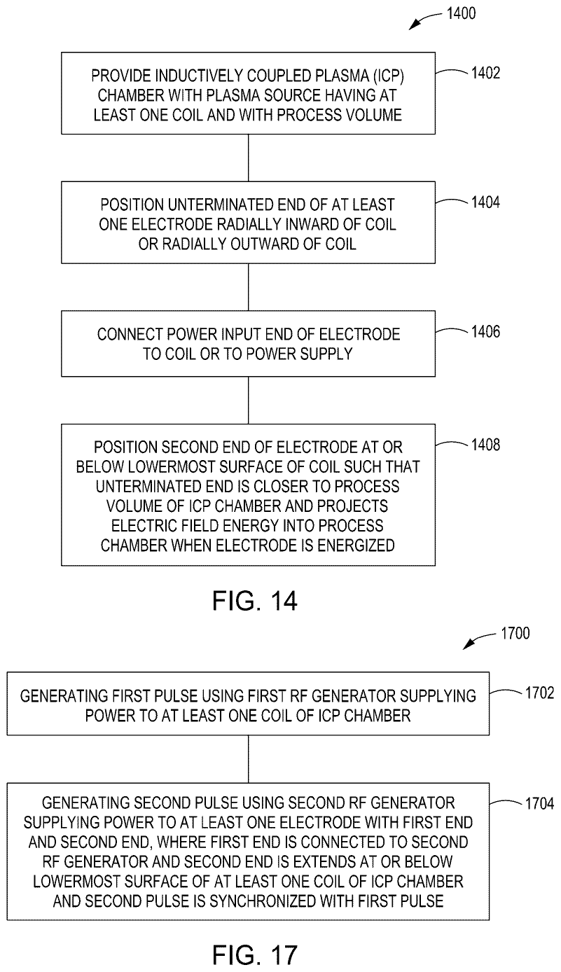

FIG. 14 is a method 1400 of projecting electric fields into a process volume of an inductively coupled plasma (ICP) chamber. In block 1402, an inductively coupled plasma (ICP) chamber is provided that has a plasma source assembly with at least one coil for generating plasma in a process volume of the ICP chamber. In some embodiments, the plasma source assembly will have an inner coil set and an outer coil set. The coils provide inductively coupled plasma in the process volume which is a high-density plasma. The coils also produce E-fields which can capacitively couple with the plasma in the process volume. However, the E-fields may produce unwanted side effects such as lid sputtering and, traditionally, most ICP systems use a grounded Faraday shield to prevent the E-fields from coupling with the plasma during operation, making ignition and restriking unlikely without retracting the shield, adding to complexity of the process chamber. Even with the shield retracted, some gases and/or low vacuum environments in the process volume make ignition and restriking difficult at best for the E-fields produced by the coils.

In block 1404, an unterminated end of at least one electrode is positioned radially inward of the at least one coil and/or radially outward of the at least one coil. In some embodiments, the at least one coil may be positioned between the inner coil set and the outer coil set. In some embodiments, the electrode may be positioned radially outward of the outer coil set. The unterminated end may also comprise a pad that can be used to adjust the surface area of the unterminated end of the electrode. The larger the pad, the greater the discharge area but the lower the E-field intensity. The smaller the pad, the smaller the discharge area but the higher the E-field intensity. The electrodes provide capacitively coupled plasma in the process volume which is a low-density plasma that aids in igniting and restriking plasma. In some embodiments, up to 20 electrodes may be symmetrically spaced around the outer coil to enhance uniformity of the E-field projection into the process volume.

In block 1406, a power input end, distal to the unterminated end of the electrode, is connected to at least one coil and/or to a power supply that supplies power to generate E-field discharge at the unterminated end. In some embodiments, an independent CCP RF generator may be used to couple the electrode to the process volume to ignite and/or restrike plasma in the process volume. In some embodiments, the CCP RF generator connected to the electrodes and the ICP RF generator connected to the coils may use a TTL synch signal to coordinate the ignition/restriking ON state or pulse of the CCP RF generator with the ON state of the ICP RF generator. In some embodiments, the pulse of the CCP RF generator may be from approximately 1 μs to approximately 10,000 ms. In some embodiments, an optical sensor may be used to monitor the plasma within the process volume and provide feedback to a controller to automatically adjust the pulse width of the CCP RF generator. As the plasma density increases, the optical sensor detects the increased density and sends data to the controller. The controller may be a controller for the ICP system and/or an electrical field controller and the like.

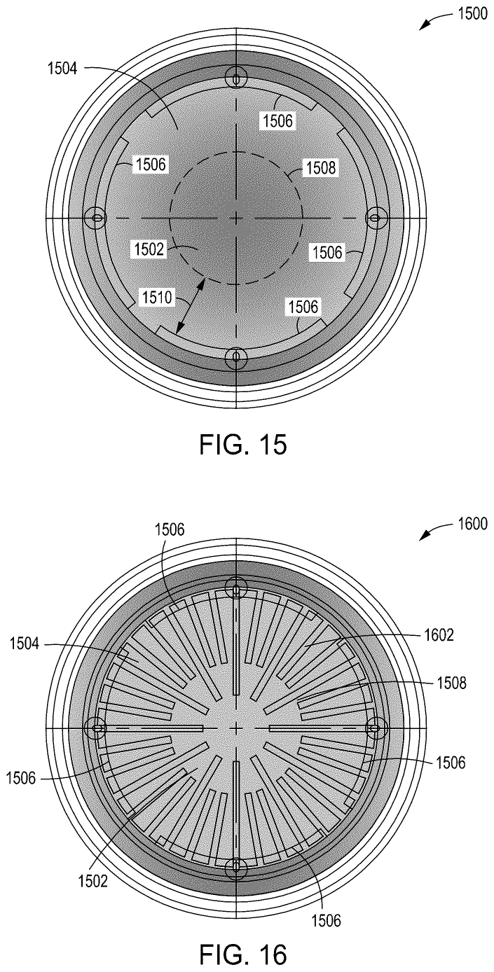

The positioning of the electrodes around the coils directly impacts the uniformity of the plasma generated in the process volume. The uniformity of the plasma, in turn, impacts the cross-uniformity of the processes performed on the substrate such as etching and depositing. In a top-down view 1500 of FIG. 15, the electric field intensity 1502 across the process volume 1504 is depicted. In the example, four electrodes with pads similar to the pads 902 of FIGS. 7-9 and 10 are symmetrical spaced above and about the process volume 1504. The pads 1506 are spaced radially outward of a substrate 1508. The distance 1510 between the substrate 1508 and the pads 1506 is selected such that any unwanted effects, such as electrical field hotspots, are diminished before reaching the substrate 1508. Generally, the more pads used, the greater the control over the E-fields and the greater the E-field uniformity. A balance can be achieved between the increased costs and complexity of the number of electrodes versus uniformity levels achieved based on the requirements for a given chamber or a given process within the chamber.

In some embodiments, as depicted in FIGS. 9, 10, and 15, the electrodes are positioned outside of the outer coil of the ICP source assembly. The outer zone placement allows for the maximum distance (e.g., distance 1510) from the pads 1506 to the periphery of the substrate 1508. In an example, a 12-inch wafer is often processed using a coil with a coil diameter of approximately 18 inches. Placement of the electrodes at a diameter of 19 to 20 inches from the center of the process volume gives a separation distance (e.g., distance 1510) of approximately 7 inches to 8 inches between the pads and the periphery of the substrate 1508 (from a top-down viewpoint). The increased distance prevents nonuniformity of the substrate processes. The distance creates greater diffusion of the negative effects of the E-fields before reaching the substrate, giving a more unified plasma density around the substrate 1508. In some instances, a high pulsing frequency (with smaller pulse width) of the ICP RF power may be more influenced by the short pulse width of the CCP RF power. As more restriking is required for a given time period, the pulsing of the CCP power has a greater influence on the plasma in the process volume. The CCP coupled plasma is of lower density and has an undesired effect on the processes performed in the process volume. By increasing the distance, the undesired effect is minimized prior to reaching the substrate 1508, increasing uniformity of the plasma acting on the substrate 1508. In some embodiments, as depicted in a top-down view 1600 of FIG. 16, a heater 1602 with a floating ground may be used to further enhance the uniformity of the plasma in the process volume of the process chamber. The heater 1602 acts as a floating Faraday shield to help unify the E-fields to increase uniformity.

In block 1408, the unterminated end of the at least one electrode is positioned at or below a lowermost surface of the at least one coil such that the unterminated end of the electrode is equal to or closer in distance to the process volume of the ICP chamber and projects E-field energy into the process volume of the ICP chamber when the at least one electrode is energized. In some embodiments, the unterminated end of the electrode may include a pad. The unterminated end may be in contact with an uppermost surface of the lid to approximately 1 inch above the uppermost surface of the lid. The distance may be manually adjusted or set for a specific chamber or for a specific process within the chamber. In some embodiments, the distance may be automatically adjusted using step motors and the like.

Another method 1700 of projecting electric fields into a process volume of an inductively coupled plasma (ICP) chamber is depicted in FIG. 17. In block 1702, a first pulse is generated using a first RF generator (e.g., RF plasma sources 118 of FIG. 1 or of FIG. 10, etc.) supplying power to at least one coil (e.g., inner coil 114, outer coil 116 of FIG. 1, etc.) of the ICP chamber (e.g., ICP chamber 100 of FIG. 1, etc.). In block 1704, a second pulse is generated using a second RF generator (e.g., RF generator 1002 of FIG. 10, etc.) supplying power to at least one electrode with a first end and a second end (e.g., pad 902 of FIGS. 9 and 10, etc.) where the first end is connected to the second RF generator and the second end is positioned at or below a lowermost surface of the at least one coil of the ICP chamber and the second pulse is synchronized with the first pulse (see, e.g., graph 1200 of FIG. 12). The synchronization signal can be provided by the first RF generator directly to the second RF generator or via an electric field controller (see, e.g., optional electric field controller 132 of FIG. 10, etc.) or via a controller (e.g., controller 146 of FIG. 10, etc.). The synchronization signal can also originate from the controller, the electric field controller, or the second RF generator (second RF generator synchronizes the first RF generator, etc.). The synchronization signal can be a TTL synchronization signal and the like. In some embodiments, the second pulse may have a pulse width of 1 μs to 10,000 ms. An optical sensor (e.g., optical sensor 156 of FIG. 1, etc.) may be positioned in the ICP chamber to monitor states of plasma and the second RF generator may alter the pulse width of the second pulse based on feedback from the optical sensor.

In some embodiments, the distance of the second end of the electrode to the process volume is adjustable, either manually or automatically. The electrode and power feed structure (e.g., first half 812, first power feed section 810, second half 912, second power feed section 910 of electrodes, electrode power feed 1050 of FIG. 10, etc.) may be operated in a resonant state as a resonate circuit (see, e.g., FIG. 13). In some embodiments, the second RF generator may be a variable power source for the electrodes. An E-field controller (e.g., optional electric field controller 132, etc.) may be connected to and in communication with the second RF generator and configured to adjust power to at least one of the electrodes. The E-field controller may adjust power the second RF generator power based on a process parameter of a process profile for the ICP chamber or based on feedback such as from an optical sensor and the like.

CCP is used at the beginning of the plasma ignition to generate seed electrons which produce plasma in the process volume of the chamber. The process chamber surfaces in the process volume have a surface charge that is energized by the CCP RF generator and the electrodes. The energized surface charge is projected into the process volume and assists with the dissociation of the gases used in the plasma. The initial ignition/restriking is due to CCP coupling (low density plasma). For ICP systems, the CCP coupling transitions to ICP coupling in order to maintain high density plasma (ICP coupled plasma) in the process volume of the process chamber. In some chamber designs, a grounded Faraday shield design may completely block all CCP coupling, making ignition/restriking of plasma very difficult regardless of the amount of ICP power available. Another variable is that the gas used for the plasma may be extremely difficult to ignite/restrike. The methods and apparatus herein allow ignition/restriking of plasma in ICP systems despite such issues.

When the electrodes are used in conjunction with a floating Faraday shield that blocks the electric fields from the coils, the capacitive coupling from the coils is dramatically reduced and the electric fields generated from the unterminated ends of the electrodes are used to tightly control the electric fields to enhance plasma maintenance, ignition, and restriking only when needed, substantially eliminating the negative impacts that electric fields have on the substrate processing in the ICP chamber. The electrodes and electrode assemblies can be designed independently of the coil geometry, allowing for cost effective retrofitting of ICP chambers. The generated electric fields can be fine-tuned by altering the number of electrode pads and/or the spacing of the electrode pads, the sizes of the electrode pads (surface area), distance of the electrode pad bottom surface to the process volume and/or lid, voltage inputs to the electrodes and subsequent voltages on the electrode pads, and the like. In some embodiments, the surface area of the electrode pads is designed to provide sufficient electric field penetration while at the same time not so large as to induce unwanted lid sputtering during electric field generation. In some embodiments, the power supply connected to the power input end of the at least one electrode may be controlled by an E-field controller on a one-by-one basis for each electrode, on a set-by-set basis for sets of electrodes, and/or on an all-electrodes basis, and the like. The E-field controller allows control of voltage levels applied to the electrode pads and also control of which electrodes are powered and also when each electrode is powered and the like. The E-field controller may operate in conjunction with an ICP chamber controller to adjust E-field projection into the process volume according to a given process and/or process profile being performed in the process volume.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. An apparatus for forming plasma in an inductively coupled plasma (ICP) chamber, comprising:
at least one coil positioned above a process volume of the ICP chamber and configured to generate inductively coupled plasma in the process volume by generating magnetic fields (H-fields) that radiate into the process volume and wherein the at least one coil is connected to a first power source; and
at least one electrode positioned above the process volume of the ICP chamber with a first end and a second end, wherein the second end is positioned at or below a lowermost surface of the at least one coil, wherein the first end is connected to a second power source independent of the first power source, and wherein the second end is configured to radiate electric fields (E-fields) into the process volume.

2. The apparatus of claim 1, wherein the second power source is a variable power source.

3. The apparatus of claim 1, wherein an E-field controller is connected to and in communication with the second power source and is configured to adjust power to at least one of the at least one electrode.

4. The apparatus of claim 3, wherein the E-field controller adjusts power based on a process parameter of a process profile for the ICP chamber.

5. The apparatus of claim 1, wherein a Faraday shield is positioned between the at least one coil and the process volume and wherein no Faraday shield is positioned between the second end of the at least one electrode and the process volume.

6. The apparatus of claim 1, wherein the second end of the at least one electrode has a second end surface area.

7. The apparatus of claim 6, wherein the second end surface area is smaller than a cross section of the at least one electrode, greater than a cross section of the at least one electrode, or equal to a cross section of the at least one electrode.

8. The apparatus of claim 1, wherein the second end of the at least one electrode is adjustably connected to a pad and wherein a distance between the process volume and the pad of the second end of the at least one electrode can be altered.

9. The apparatus of claim 1, wherein the at least one electrode is a plurality of electrodes and wherein the second end of at least two of the plurality of electrodes are connected to one pad.

10. An apparatus for forming plasma in an inductively coupled plasma (ICP) chamber, comprising:
at least one coil positioned above a process volume of the ICP chamber and configured to generate inductively coupled plasma in the process volume by generating magnetic fields (H-fields) that radiate into the process volume and wherein the at least one coil is connected to a first power source; and
at least one electrode positioned above the process volume of the ICP chamber with a first end and a second end, wherein the second end is positioned at or below a lowermost surface of the at least one coil, wherein the first end is connected to a second power source independent of the first power source, and wherein the second end is configured to radiate electric fields (E-fields) into the process volume,
wherein a floating Faraday shield is positioned between the at least one coil and the process volume,
wherein the at least one electrode is a plurality of electrodes, and wherein the at least one coil includes an inner coil and an outer coil.

11. The apparatus of claim 10, wherein the second end of the at least one electrode has a second end surface area.

12. The apparatus of claim 11, wherein the second end surface area is smaller than a cross section of the at least one electrode, greater than a cross section of the at least one electrode, or equal to a cross section of the at least one electrode.

13. The apparatus of claim 10, wherein the second end of the at least one electrode is adjustably connected to a pad and wherein a distance between the process volume and the pad of the second end of the at least one electrode can be altered.

14. The apparatus of claim 10, wherein the at least one electrode is a plurality of electrodes and wherein the second end of at least two of the plurality of electrodes are connected to one pad.

15. An apparatus for forming plasma in an inductively coupled plasma (ICP) chamber, comprising:
a first RF power source electrically connected to at least one coil of the ICP chamber, wherein the at least one coil is configured to inductively couple with plasma formed in a process volume of the ICP chamber; and
a second RF power source electrically connected to at least one electrode with an unterminated end of the at least one electrode positioned radially outward of the at least one coil and configured to capacitively couple with plasma formed in the process volume of the ICP chamber,
wherein the first RF power source is configured to generate a synchronization signal which is sent to the second RF power source when power from the first RF power source is turned ON and wherein the second RF power source is configured to pulse power when the synchronization signal is received from the first RF power source.

16. The apparatus of claim 15, wherein the second RF power source is configured to pulse power with a pulse having a pulse width of 1 μs to 10,000 ms.

17. The apparatus of claim 15, wherein an optical sensor is positioned in the ICP chamber to monitor states of plasma and wherein the second RF power source is configured to alter a pulse width based on feedback from the optical sensor.

18. The apparatus of claim 15, wherein a distance from the unterminated end of the at least one electrode to the process volume is adjustable.

19. The apparatus of claim 18, wherein the distance is automatically adjustable.

20. The apparatus of claim 15, wherein the at least one electrode and power feed structure are configured to operate in a resonant state.
